(19) United States
(12) Patent Application Publication
(10) Pub. No.: US 2017/0352458 A1
(43) Pub. Date: Dec. 7, 2017

(54) PLANAR COIL

(71) Applicant: X-FAB Semiconductor Foundries AG, Erfurt (DE)

(72) Inventors: Ralf LERNER, Erfurt (DE); Siegfried HERING, Erfurt (DE)

(21) Appl. No.: 15/615,258

(22) Filed: Jun. 6, 2017

(30) Foreign Application Priority Data
Jun. 6, 2016 (DE) 102016110425.6

(51) Int. Cl. H01F 5/04; G01R 15/18; H01F 27/28; H01F 5/06; H01F 27/32

(52) U.S. Cl. CPC H01F 5/04; H01F 27/28; H01F 5/06; G01R 15/18; H01F 2005/043; H01F 2027/329

(57) ABSTRACT

Individual coils as well as two or more coils arranged one over the other or one coil in combination with a sensor, which can be integrated into planar semiconductor technology are described. A coil comprises a turn and two supply lines for supplying current to the coil. The turn and the supply lines are formed from a metal layer. One of the two supply lines is connected to a first end of the turn and the other of the two supply lines is connected to a second end of the turn.

The invention relates to coils, individual coils as well as two or more coils arranged one over the other or a coil in combination with a sensor, which may be integrated into planar semiconductor technology.

Spiral-shaped coils that are shown in U.S. Pat. No. 6,114,937, for example, are typically produced from two metal layers. Thus, a spiral-shaped metal line can be formed from a first metal layer. In order to contact the inner end of the metal line, underpass contacts, for example, that are arranged below the metal line can be used. Underpass contacts can be formed by a second metal layer and can be connected, for example, to the inner end of the metal line by means of vias filled with metal.

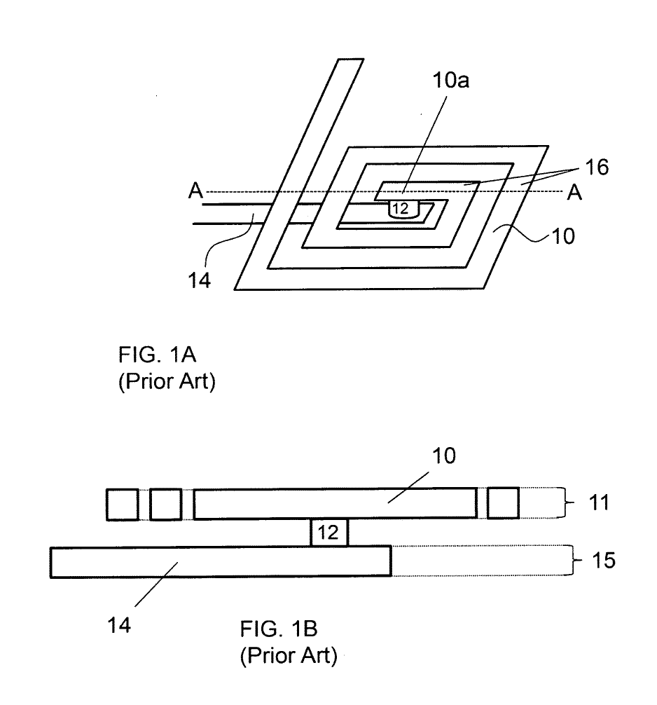

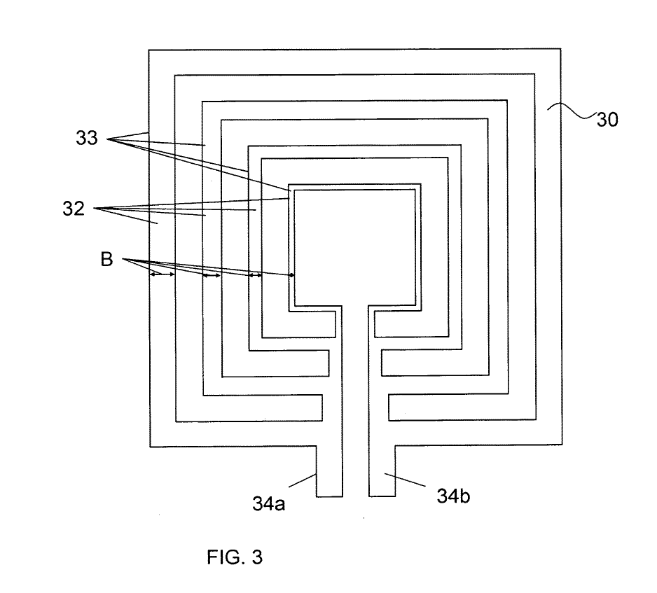

Taken from DE10 2012 018 013, FIG. 3 is partially incorporated as prior art into the present description as FIG. 1A. The planar coil 10 known from this prior art consists of a first metal layer and includes several turns 16 that are arranged to be spiral-shaped. As also shown in section in FIG. 1B, the electric supply into the centre 10a of the coil 10 takes place by means of a via contact 12 that is arranged between the first metal layer 11 and a second metal layer 15. In the embodiment of the prior art in FIGS. 1A and 1B, the electric supply takes place via a supply line 14 that has been formed in the second metal layer 15. The supply line 14 in the second metal layer 15 runs below the coil 10 to the centre 10a of the coil, wherein the supply line 14 partially crosses the coil 10, or crosses some turns 16 of the coil 10.

However, the inventors of the present application have recognised that the vias or via contacts contribute to the total resistance of the coil and may also limit the maximum current-carrying capacity of the coil. The second metal layers and the vias or via contacts also enlarge the vertical extension or the total thickness of an individual coil, which may become noticeable, in particular in an arrangement of several spiral-shaped coils above one another.

The inventors have also recognised that, in spiral-shaped coils, the individual turns of the coil are arranged in series. Thus, a total resistance of the coil results from the sum of the resistance per turn. An increase of inductivity of the coil due to an increase in the number of turns thus results in a higher total resistance of the coil.

Starting from the prior art, the object of the invention is to make it possible to produce an improved coil which can be integrated into planar semiconductor technology.

This and other problems may be solved, for example, by the features specified in claims 1, 14, 15 and 16.

Advantages of certain exemplary embodiments of this invention include a reduction of the vertical extension of a coil, for example by forming the coil and the supply lines for supplying current to the coil from a metal layer. Thus, individual planar coils may be produced, for example from one metal layer. Furthermore, two or more coils may be arranged above one another, wherein the vertical extension or the total thickness of the individual coils may be reduced. The individual coils in this arrangement may, for example, be contacted by a single wiring plane per coil.

In certain exemplary embodiments, the coil may include a number of turns that are arranged in parallel, such as for example at least two turns arranged in parallel. As a result of the parallel arrangement of a number of turns, the total resistance of the coil may be decreased, whereby, with equally applied voltage, an increased current may flow through the coil. This increased current generates an increased magnetic flux density. By increasing the number of parallel arranged turns, the total resistance of the coil may be reduced.

In certain exemplary embodiments, instead of or in addition to increasing a number of turns, the width of a or each turn of the coil may be increased. The ratio between the thickness and the width of a or each turn may encompass a range of about 1:25 to 1:5. By increasing the width of one turn, the cross-sectional surface of the respective turn may be increased, which may lead to a reduction of the resistance of the respective turn. The turn of the coil may be formed by a conductor track. The thickness of a turn may correspond to the thickness of the conductor track and/or the width of the turn may correspond to the width of the conductor track. The width of the turn is therefore to be distinguished from the total diameter of the turn or the coil.

Further advantageous embodiments of the subject matter of claims 1, 14, 15 and 16 are specified in the s dependent claims.

The invention will now be described by means of different exemplary embodiments of the invention with reference to the accompanying drawings, which show:

FIG. 1A as prior art, a planar, spiral-shaped coil made of a first metal layer, in which the supply into the centre of the coil takes place via a second metal layer and a via contact,

FIG. 1B a cross-section of the coil of FIG. 1A along the dotted line A-A,

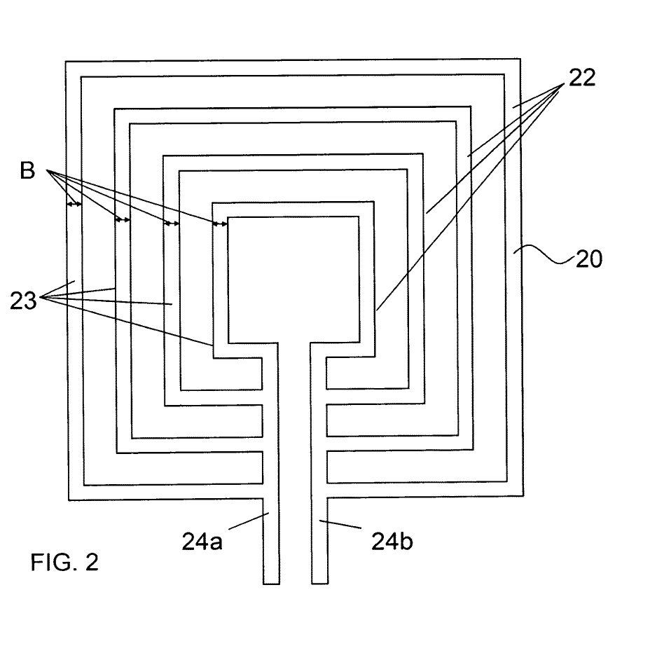

FIG. 2 a planar coil formed of a metal layer, in which a number of turns having the same width are concentrically arranged and electrically arranged in parallel by supply lines for supplying current to the coil,

FIG. 3 a planar coil formed of a metal layer, in which a number of turns having different widths are concentrically arranged and electrically arranged in parallel by supply lines for supplying current to the coil,

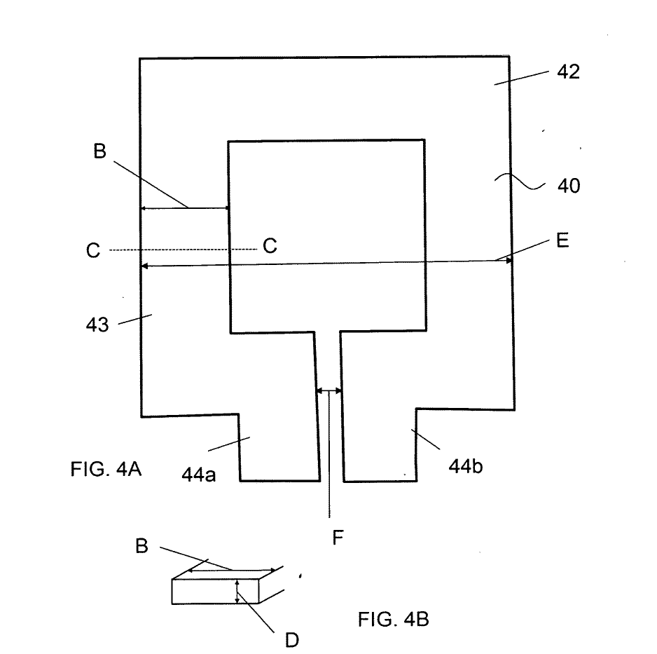

FIG. 4A a planar coil having one turn, in which the supply lines are connected to the ends of the turn and the turn and the supply lines are formed from a metal layer,

FIG. 4B a cross-section of the turn of the coil of FIG. 4A along the dotted line C-C,

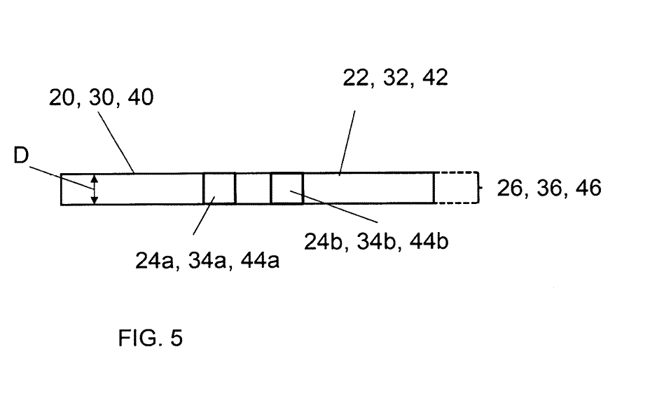

FIG. 5 a front view of the coil of FIG. 2, FIG. 3 or FIG. 4A,

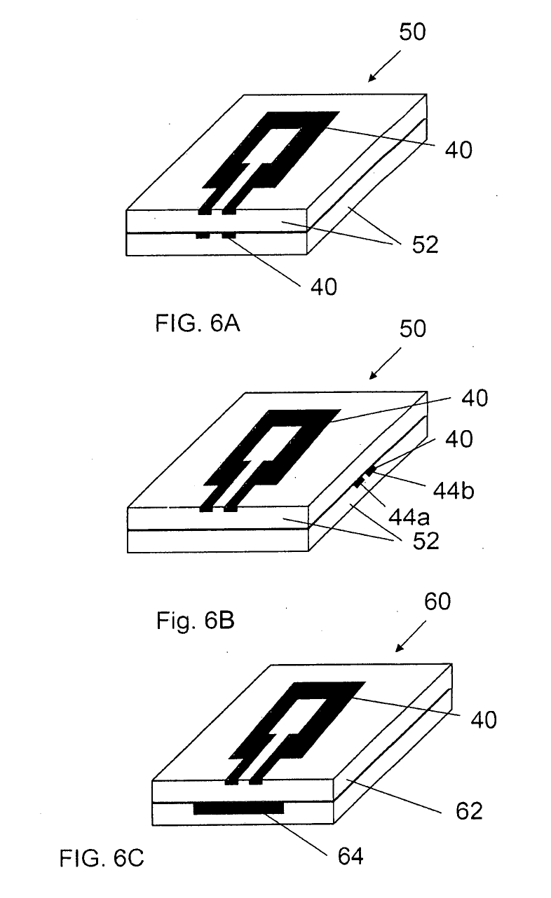

FIG. 6A an arrangement of two planar coils above one another,

FIG. 6B an arrangement of two planar coils above one another and offset relative to each other,

FIG. 6C an arrangement of a planar coil and a sensor.

FIG. 2 shows a first exemplary embodiment of a planar coil 20 that can be integrated into planar semiconductor technology, such as silicon semiconductor technology or CMOS silicon semiconductor technology, for example. The planar coil 20 in FIG. 2 includes a number of turns 22. Each turn 22 of the coil 20 is formed by a respective curved conductor track 23. In the exemplary embodiment in FIG. 2, the coil 20 has four turns 22, wherein the coil 20 may have more than four or less than four turns in other exemplary embodiments. For example, in other exemplary embodiments, the coil 20 may have only a single turn.

In the coil 20 shown in FIG. 2, the turns 22 are arranged to be concentric relative to one another. A first end of each turn 22 is connected to a first supply line 24a and a second end of each turn 22 is connected to a second supply line 24b. By connecting the first and second ends of the turns 22 to respective first and second supply lines 24a, 24b, the turns 22 are electrically arranged in parallel. The total resistance of the coil 20 decreases as a result of the parallel arrangement of the turns 22 and thus, the current that can flow through the coil 20, with the same voltage being applied, is increased, wherein the current generates an increased magnetic flux density. As a result of an increase in the number of parallel arranged turns 22, the total resistance of the coil may be further reduced.

In the coil 20 shown in FIG. 2, the first and second supply lines 24a, 24b of the turns 22 are arranged to extend outwardly. In this exemplary embodiment, the first and second supply lines 24a, 24b extend parallel to each other from the ends of the turns 22 to a region outside of the footprint of the turns 22.

In FIG. 2, the width B of the conductor track 23 of each turn 22 is the same, wherein in other exemplary embodiments, the width of the conductor track 23 of the individual turns may be different.

FIG. 3 shows a further exemplary embodiment of a planar coil 30, which is similar to the exemplary embodiment shown in FIG. 2. In the exemplary embodiment of FIG. 3, the conductor tracks 33 of the turns 32 have different widths B, wherein the width B of the conductor track 33 of the turn 32 that is arranged in the centre of the coil 30 is the smallest and the width B of the conductor track 33 of the turn 32 that is arranged on the outermost edge of the coil 30 is the greatest. In this exemplary embodiment, the width of the conductor track 33 of the turn 32 that is arranged on the outermost edge of the coil 30 corresponds to three times the width of the conductor track 33 of the turn 32 that is arranged in the centre of the coil 30. For example, the conductor track 33 of the turn 32 that is arranged in the centre of the coil 30 may have a width of about 1 m and the conductor track 33 of the turn 32 that is arranged on the outermost edge of the coil 30 may have a width of about 3 μm. However, in other exemplary embodiments, the width B of the conductor track 33 of the turn that is arranged in the centre of the coil may encompass a range of 0.5 to 2 μm and the width B of the conductor track of the coil 32 that is arranged on the outermost edge of the coil 30 may encompass a range of 1.5 to 6 μm. In this exemplary embodiment, the width of the conductor tracks 33 of the individual turns 32 thus increases with the diameter of the turns 32. However, in other exemplary embodiments, the width of the conductor tracks 33 of the turns 32 may decrease with the diameter of the turns. In the arrangement of the turns 32 of the coil 30 shown in FIG. 3, the turns 32 have different lengths. The different widths B of the conductor tracks 33 of the turns 32 may be used to compensate for the different lengths of the turns and to vary and/or adjust the resistance of each turn 32. The current supply again takes place by means of supply lines 34a, 34b that are common for all turns 32 and are arranged to extend outwardly from the turns 32 in this exemplary embodiment. The first and second supply lines 34a, 34b also extend in parallel to each other from the ends of the turns 32 to a region outside the footprint of the turns 32.

A further exemplary embodiment of a planar coil 40 is shown in FIG. 4A. The coil 40 shown in FIG. 4A is similar to the coils 20, 30 shown in FIG. 2 and FIG. 3. In contrast to the coils 20, 30 shown in the exemplary embodiment above, the coil 40 in this exemplary embodiment only has one turn 42. As in the exemplary embodiments above, the single turn 42 is formed by a curved conductor track 43. In comparison, for example, to the turns 22 of the coil 20 shown in FIG. 2, the width of the conductor track 43 in this exemplary embodiment is greater. The current supply to the coil 40 takes place by means of supply lines 44a, 44b, wherein the first and second supply lines 44a, 44b are in turn arranged to extend outwardly from the turn 43.

In this exemplary embodiment, the width of the conductor track 43 is greater than the width of the conductor tracks 23, 33 of the coils 20, 30 shown in FIG. 2 and FIG. 3. In the exemplary embodiment of FIG. 4A, the width B of the conductor track 43 is greater than a distance F between the first and second supply lines 44a, 44b. For example, the width of the conductor track 43 of the coil 40 shown in FIG. 4A can correspond to about 25% of the total diameter E of the coil 40. In other exemplary embodiments, the width of the conductor track may correspond, for example, to between 20′% and 35% of the total diameter of the coil.

FIG. 4B shows a cross-section of the conductor track 43 of the turn 42 in this exemplary embodiment. As a result of the greater width B of the conductor track 43 in FIG. 4A and FIG. 4B, the resistance of the single turn 42 is smaller than the resistance of an individual turn 22 in the coil 20 shown in FIG. 2, provided that the thickness D of the conductor tracks 23, 43 is the same. This means that, instead of or in addition to an increase in the number of turns, the width B of a or each turn of a coil may be increased in order to reduce the resistance of the coil. The ratio between the thickness D and the width B of the conductor track 43 in this exemplary embodiment may encompass, for example, a range of about 1:25 to 1:5. For example, the width B of the conductor track 43 of the coil 40 in FIG. 4A may encompass a range of about 5 to 100 μm, wherein the thickness D may encompass a range of about 0.2 to 20 μm.

In the exemplary embodiments of FIG. 2, FIG. 3 and FIG. 4A, the or each turn 22, 32, 42 defines an angle of about 300° to 320°. The angle may be defined by means of the extent of the or each turn 22, 32, 42 from the first supply line 24a, 34a, 44a to the second supply line 24b, 34, 44b. In other exemplary embodiments, the or each turn may define an angle of at least 270° and/or an angle of 350° at most.

FIG. 5 shows a schematic front view of the coil 20, 30, 40 shown in FIG. 2, FIG. 3 or FIG. 4A. In the exemplary embodiments above, the turns 22, 32, 42 of the coils 20, 30, 40 and the first and second supply lines 24a, 24b, 34a, 34b, 44a, 44b are formed by a metal layer 26, 36, 46. In FIG. 5, the turns 22, 32, 42 of the coil 20, 30, 40 and the first and second supply lines 24a, 24b, 34a, 34b, 44a, 44b substantially have a thickness D of the metal layer 26, 36, 46. Thus, the vertical extension of the respective coil 20, 30, 40 or of the turn(s) 22, 32, 42 and the first and second supply lines 24a, 24b, 34a, 34b, 44a, 44b substantially correspond to the thickness D of the respective metal layer 26, 36, 46. The thickness D of the metal layer 26, 36, 46 also determines a thickness D of the conductor track 23, 33, 43 of the or each of the turns 22, 32, 42.

By forming the coils 20, 30, 40 and the corresponding first and second supply lines 24a, 24b, 34a, 34b, 44a, 44b by means of a metal layer 26, 36, 46, no via contacts are necessary and the individual coils may be contacted, for example, on an outer region of each coil. Since the coils 20, 30, 40 in the exemplary embodiments above do not require any via contacts, the resistance of each coil 20, 30, 40 may be reduced.

The formation of the coils 20, 30, 40 and the first and second supply lines 24a, 24b, 34a, 34b, 44a, 44b by means of a metal layer 26, 36, 46 also allows for an arrangement of several planar coils above one another.

FIG. 6A shows an exemplary embodiment of an arrangement 50 in which two coils 40 are shown as being arranged above one another, wherein in other exemplary embodiments more than two coils may be arranged above one another.

The coils 40 in FIG. 6A and FIG. 6B correspond to the coil 40 shown in FIG. 4A. In other exemplary embodiments, the arrangement 50 can include, for example, the coils 20, 30 shown in FIG. 2 and/or FIG. 3. FIG. 6A shows that the individual coils 40 are formed by a respective metal layer 46 and are arranged in or on an insulator layer 52, wherein the insulator layer 52 of the upper coil 40 is arranged between the two coils 40 and, as a result, the two coils 40 are electrically insulated from each other. For example, the insulator layer 52 can be formed by an ILD (Inter Layer Dielectric) or via oxide.

In the exemplary embodiment shown in FIG. 6B, the upper coil 40 is arranged to be offset by 90° relative to the lower coil 40. As a result of this arrangement, the supply lines 44a, 44b of the upper coil 40 extend in a direction offset by 90° relative to the supply lines of the lower coil 40. In other exemplary embodiments, other arrangements of the upper and lower coils could be provided. For example, the two coils may be arranged to be offset relative to one another by 180° or 270°.

The coils 40 shown in FIG. 6A and FIG. 6B can be the same or different.

Since each individual coil 40 in the exemplary embodiments of FIG. 6A and FIG. 6B are formed by a corresponding metal layer 46, a wiring plane, for example, per coil 40 may be used in order to contact the individual coils 40. By omitting the via contacts in such an arrangement, the number of necessary metal layers and thus, the vertical extension or total thickness of the arrangement and/or of each individual coil may be reduced. An arrangement of several planar coils 40 above one another may be used, for example, in semiconductor components, such as for example in semiconductor transformers. When the coils are used in semiconductor transformers, the respective coils 40 may be provided, for example, with a ferrite core that is integrated into the respective coils in order to increase the magnetic field produced by the coil.

FIG. 6C shows a further exemplary embodiment of a coil arrangement 60. The coil arrangement 60 in FIG. 6C is similar to the coil arrangement 50 in FIG. 6A. The arrangement in FIG. 6C includes a coil 40 in combination with a sensor 64, such as for example a Hall sensor 64, wherein, in this exemplary embodiment, the coil 40 is arranged above the Hall sensor. In this exemplary arrangement 60, the coil 40 may be used to generate the magnetic field and the Hall sensor 64 for detecting the magnetic field generated by the coil 40. In other exemplary embodiments, the arrangement 60 may include, for example, the coil 20, 30 shown in FIG. 2 or FIG. 3. In certain exemplary embodiments, the Hall sensor 64 may also be formed by a metal layer.

The coils 20, 30, 40 in the exemplary embodiments above may be formed, for example, from metal and/or metal alloys, which may include aluminium, tin, gold, silver, aluminium silicon, aluminium copper, aluminium silicon copper and/or copper. The metal layer of the coil 20, 30, 40 may be arranged, for example, in or on a non-conductor layer or insulator layer that is formed on a semiconductor substrate or wafer, such as for example germanium (Ge), silicon (Si), SOI (silicon on a non-conductor or “silicon-on-insulator”) or SOS (“silicon on sapphire”). In other exemplary embodiments, the semiconductor substrate may include, for example, silicon germanium (SiGe), gallium arsenide (GaAs), indium phosphide (InP), indium arsenide (InAs) or other III-V semiconductors.

An exemplary method for producing the coils 20, 30, 40 may include, for example, depositing the metal layer, photochemistry, etching of the semiconductor substrate, the Damascene process and/or photochemistry in combination with electroplating.

Although in the exemplary embodiments above the turns of the coils 20, 30, 40 are shown in a substantially square or rectangular shape, the turns of the coils may comprise other shapes in other exemplary embodiments, such as for example circular, elliptical or oval.

Although in the exemplary embodiments above the turns 22, 32 are arranged concentrically, the turns may also be arranged relative to one another in a different manner. For example, the turns may be arranged to be eccentrical relative to one another.

In the exemplary embodiments above, the supply lines 24a, 24b, 34a, 34b, 44a, 44b may be comprised in the respective coils 20, 30, 40. In other exemplary embodiments, the supply lines may be provided separately from the coils.

### LIST OF REFERENCE NUMERALS

20 Coil according to a first exemplary embodiment
22 Turns of the coil 20
23 Conductor track of the turns 22
24a First supply line of the coil 20
24b Second supply line of the coil 20
26 Metal layer of the coil 20
30 Coil according to a second exemplary embodiment
32 Turns of the coil 30
33 Conductor track of the turns 32
34a First supply line of the coil 30
34b Second supply line of the coil 30
36 Metal layer of the coil 30
40 Coil according to a third exemplary embodiment
42 Turn of the coil 40
43 Conductor track of the turn 42
44a First supply line of the coil 40
44b Second supply line of the coil 40
46 Metal layer of the coil 40
50 Coil according to a fourth exemplary embodiment
52 Insulator layer of a fourth exemplary embodiment
60 Coil according to a fifth exemplary embodiment
62 Insulator layer of a fifth exemplary embodiment
64 Sensor
B Width of the conductor track 42 of the turn 42 or of the turns 22, 32
D Thickness of the metal layer 26, 36, 46 and/or the conductor track of the turn 42 or the turns 22,
E Total diameter of the turn 42
F Distance between the first and second supply lines 44a, 44b of the coil 40

1. A coil configured for integration into planar semiconductor technology, the coil comprising:
a turn and two supply lines for supplying current to the coil, the turn and the supply lines being formed from a metal layer and one of the two supply lines being connected to a first end of the turn and the other of the two supply lines being connected to a second end of the turn.

2. The coil according to claim 1, wherein the coil and the supply lines substantially comprise a thickness of the metal layer.

3. The coil according to claim 1, wherein the supply lines are arranged to extend outwardly from the turn.

4. The coil according to claim 1, comprising at least two turns, wherein one of the two supply lines connects a first end of each turn and the other of the supply lines connects a second end of each turn.

5. The coil according to claim 4, wherein the turns are arranged in parallel by the supply lines.

6. The coil according to claim 4, wherein the turns are concentrically arranged.

7. The coil according to claim 4, wherein each turn is formed by a conductor track and the conductor track has a width.

8. The coil according to claim 7, wherein the width of each conductor track of the turns is the same.

9. The coil according to claim 7, wherein the width of each conductor track of the turns is different.

10. The coil according to claim 7, wherein the width of the conductor track of the external turns is greater than the width of the conductor track of the internal turns.

11. The coil according to claim 1, wherein the turn is formed by a conductor track that has a width and a thickness, and a ratio between the thickness and width of the conductor track encompasses a range of about 1:25 to 1:5.

12. The coil according to claim 1, wherein a/the width of a/the conductor track of a/the turn encompasses a range of about 5 to 100 μm and/or a/the thickness of a/the conductor track of a/the turn encompasses a range about 0.2 to 20 μm.

13. The coil according to claim 1, wherein the coil comprises a planar coil or a flat coil.

14. A coil configured for integration into planar semiconductor technology, wherein the coil comprises a number of turns arranged in parallel and the coil is formed from a metal layer.

15. A coil configured for integration into planar semiconductor technology, wherein the coil comprises a turn and the coil is formed from a metal layer, wherein the turn is formed by a conductor track that has a width and a thickness and the ratio between the thickness and width encompasses a range of about 1:25 to 1:5.

16. A coil configured for integration into planar semiconductor technology, wherein the coil comprises a turn and the coil is formed from a metal layer, wherein the turn defines an angle of at least 270° and/or an angle of 350° at most.

17. A coil arrangement, wherein the coil arrangement comprises two coils according to claim 1, wherein the two coils are arranged above one another.

18. A coil arrangement, wherein the coil arrangement comprises at least one coil according to claim 1 and a sensor for detecting a magnetic field generated by the coil.
